(19) United States
(12) Patent Application Publication
(10) Pub. No.: US 2015/0064921 A1
(43) Pub. Date: Mar. 5, 2015

(54) LOW TEMPERATURE PLASMA ANNEAL PROCESS FOR SUBLIMATIVE ETCH PROCESSES

(71) Applicant: Applied Materials, Inc., Santa Clara, CA (US)

(72) Inventors: Srinivas D. NEMANI, Sunnyvale, CA (US); Sean S. KANG, San Ramon, CA (US); Jeremiah T. P. PENDER, San Jose, CA (US); Chia-Ling KAO, San Jose, CA (US); Sergey G. BELOSTOTSKIY, Sunnyvale, CA (US); Lina ZHU, San Jose, CA (US)

(21) Appl. No.: 14/015,557

(22) Filed: Aug. 30, 2013

(51) Int. Cl. H01L 21/311

(52) U.S. Cl. CPC H01L 21/31116
USPC 438/715

(57) ABSTRACT

Methods for etching a material layer disposed on the substrate using a low temperature etching process along with a subsequent low temperature plasma annealing process are provided. In one embodiment, a method for etching a material layer disposed on a substrate includes transferring a substrate having a material layer disposed thereon into an etching processing chamber, supplying an etching gas mixture into the processing chamber, remotely generating a plasma in the etching gas mixture to etch the material layer disposed on the substrate, and plasma annealing the material layer at a substrate temperature less than 100 degrees Celsius.

### BACKGROUND OF THE INVENTION

1. Field of the Invention

Embodiments of the present invention generally relate to methods for forming semiconductor devices. More particularly, embodiments of the present invention generally relate to methods for etching a material layer disposed on a substrate using a low temperature plasma annealing process for manufacturing semiconductor devices.

2. Description of the Related Art

Reliably producing sub-half micron and smaller features is one of the key technology challenges for next generation very large scale integration (VLSI) and ultra large-scale integration (ULSI) of semiconductor devices. However, as the limits of circuit technology are pushed, the shrinking dimensions of VLSI and ULSI interconnect technology have placed additional demands on processing capabilities. Reliable formation of gate structures on the substrate is important to VLSI and ULSI success and to the continued effort to increase circuit density and quality of individual substrates and die.

A patterned mask, such as a photoresist layer, is commonly used in forming structures, such as gate structure, shallow trench isolation (STI), bit lines and the like, on a substrate by an etching process. The patterned mask is conventionally fabricated by using a lithographic process to optically transfer a pattern having the desired critical dimensions to a layer of photoresist. The photoresist layer is then developed to remove undesired portion of the photoresist, thereby creating openings in the remaining photoresist.

In order to enable fabrication of next generation devices and structures, the geometry limits of the structures designed to be formed for the semiconductor devices has been pushed against technology limits, the need for accurate process control for the manufacture of small critical dimensional structures with high aspect ratio has become increasingly important. Poor process control during etching process will result in irregular structure profiles and line edge roughness, thereby resulting in poor line integrity of the formed structures. Additionally, irregular profiles and growth of the etching by-products formed during etching may gradually block the small openings used to fabricate the small critical dimension structures, thereby resulting in bowed, distorted, toppled, or twisted profiles of the etched structures.

Furthermore, the similarity between the materials selected for the hardmask layer and the adjacent layers disposed in the film stack, and even the underlying material on the substrate, may also result in similar etch properties therebetween, thereby resulting in poor selectivity during etching. Poor selectivity between the hardmask layer, adjacent layers and the materials on the substrate may result in non-uniform, tapered and deformed profile of the hardmask layer, thereby leading to poor pattern transfer and failure of accurate structure dimension control. The chemical etchant used in the etch process is required to have a greater etch selectivity for the material layers in the film stack. That is, the chemical etchant etches the one or more layers of the film stack at a rate much faster than the energy sensitive resist or the materials disposed on the substrate. The etch selectivity to the one or more material layers of the film stack over the resist prevents the energy sensitive resist from being consumed prior to completion of the pattern transfer. Thus, a highly selective etchant enhances accurate pattern transfer. However, conventional etchants are not selective enough to enable robust manufacturing of next generation devices.

In most cases, a slow etching process, such as etching rate less than 170 Å per minute, is also utilized to improve the etching selectivity so as to prevent over-etching to the underlying structures. However, the slow etching process may significantly impact the throughput of the etching process, thereby increasing manufacture cost and reducing process cycle time.

Thus, there is a need for improved methods for etching a material layer with high aspect ratio for manufacturing semiconductor devices with high etching selectivity, high throughput and accurate process and profile control.

### SUMMARY

Methods for etching a material layer disposed on the substrate using a low temperature etching process along with a subsequent low temperature plasma annealing process are provided. In one embodiment, a method for etching a material layer disposed on a substrate includes transferring a substrate having a material layer disposed thereon into an etching processing chamber, supplying an etching gas mixture into the processing chamber, remotely generating a plasma in the etching gas mixture to etch the material layer disposed on the substrate, and plasma annealing the material layer at a substrate temperature less than 100 degrees Celsius.

In another embodiment, a method for etching a material layer disposed on a substrate includes performing an etching process in a processing chamber to etch a material layer exposed by a patterned mask layer disposed on a substrate, wherein a substrate temperature during the etching process is controlled less than about 100 degrees Celsius, and performing a plasma anneal process on the etched material layer in the processing chamber, wherein the substrate temperature during the plasma anneal process is controlled less than about 100 degrees Celsius.

In yet another embodiment, a method for etching a material layer on a substrate includes transferring a substrate having a material layer into a processing chamber, remotely generating a plasma from an etching gas mixture that includes an ammonium gas and a nitrogen trifluoride, controlling a substrate temperature less than about 100 degrees Celsius, etching the material layer from the substrate utilizing the etching gas mixture, subsequently supplying a plasma anneal gas mixture into the processing chamber, applying less than about 300 Watts of a RF bias power to the plasma anneal gas mixture, controlling the substrate temperature less than about 100 degrees Celsius, and sublimating an etching byproduct from the substrate.

### BRIEF DESCRIPTION OF THE DRAWINGS

So that the manner in which the above recited features of the present invention can be understood in detail, a more particular description of the invention, briefly summarized above, can be had by reference to embodiments, some of which are illustrated in the appended drawings. It is to be noted, however, that the appended drawings illustrate only typical embodiments of this invention and are therefore not to be considered limiting of its scope, for the invention can admit to other equally effective embodiments.

FIG. 1 is a cross section view of an illustrative processing chamber in which embodiments of the invention may be practiced;

FIG. 2 is a schematic top-view diagram of an illustrative multi-chamber processing system;

FIG. 3 depicts a flow diagram for etching a material layer using a low temperature etching process followed by a low temperature plasma anneal process in accordance with one embodiment of the present invention; and

FIGS. 4A-4C depict cross-sectional views of a material layer disposed on a semiconductor substrate over a sequence for etching the material layer in accordance with one embodiment of the present invention.

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this invention and are therefore not to be considered limiting of its scope, for the invention may admit to other equally effective embodiments.

### DETAILED DESCRIPTION

Methods for low temperature etching a material layer followed by a low temperature plasma anneal process are disclosed herein which provide an etching process with high etching selectivity and accurate profile control. In one embodiment, the etching process includes using a low temperature etching process along with a low temperature plasma anneal process to assist removing etching byproducts from the substrate. The combination of the low temperature etching process followed by the low temperature plasma anneal process can provide an etching process with high etching selectivity while maintaining process throughput comparable to conventional processes to minimize the manufacturing cost.

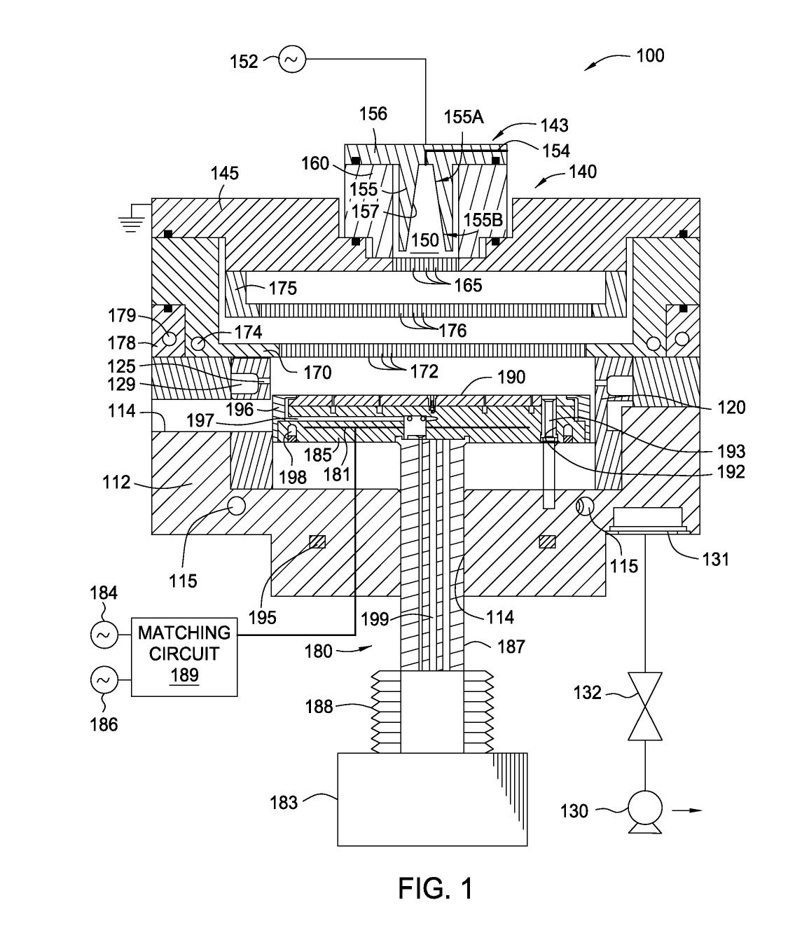

FIG. 1 is a cross sectional view of an illustrative processing chamber 100 suitable for conducting an etching process as further described below. The chamber 100 is configured to remove materials from a material layer disposed on a substrate surface. The chamber 100 is particularly useful for performing the plasma assisted dry etch process. One processing chamber 100 suitable for practicing the invention is a Siconi™ processing chamber which is available from Applied Materials, Santa Clara, Calif. It is noted that other vacuum processing chambers available from other manufactures may also be adapted to practice the present invention.

The processing chamber 100 provides both heating and cooling of a substrate surface without breaking vacuum. In one embodiment, the processing chamber 100 includes a chamber body 112, a lid assembly 140, and a support assembly 180. The lid assembly 140 is disposed at an upper end of the chamber body 112, and the support assembly 180 is at least partially disposed within the chamber body 112.

The chamber body 112 includes a slit valve opening 114 formed in a sidewall thereof to provide access to an interior of the processing chamber 100. The slit valve opening 114 is selectively opened and closed to allow access to the interior of the chamber body 112 by a wafer handling robot (not shown).

In one or more embodiments, the chamber body 112 includes a channel 115 formed therein for flowing a heat transfer fluid therethrough. The heat transfer fluid can be a heating fluid or a coolant and is used to control the temperature of the chamber body 112 during processing. Control of the temperature of the chamber body 112 is important to prevent unwanted condensation of the gas or byproducts on the interior of the chamber body 112. Exemplary heat transfer fluids include water, ethylene glycol, or a mixture thereof. An exemplary heat transfer fluid may also include nitrogen gas.

The chamber body 112 can further include a liner 120 that surrounds the support assembly 180. The liner 120 is removable for servicing and cleaning. The liner 120 can be made of a metal such as aluminum, a ceramic material, or any other process compatible material. The liner 120 can be bead blasted to increase surface roughness and/or surface area which increases the adhesion of any material deposited thereon, thereby preventing flaking of material which results in contamination of the processing chamber 100. In one or more embodiments, the liner 120 includes one or more apertures 125 and a pumping channel 129 formed therein that is in fluid communication with a vacuum port 131. The apertures 125 provide a flow path for gases into the pumping channel 129, which provides an egress for the gases within the processing chamber 100 to the vacuum port 131.

A vacuum system is coupled to the vacuum port 131. The vacuum system may include a vacuum pump 130 and a throttle valve 132 to regulate flow of gases through the processing chamber 100. The vacuum pump 130 is coupled to a vacuum port 131 disposed in the chamber body 112 and therefore, in fluid communication with the pumping channel 129 formed within the liner 120. The terms “gas” and “gases” are used interchangeably, unless otherwise noted, and refer to one or more precursors, reactants, catalysts, carrier, purge, cleaning, combinations thereof, as well as any other fluid introduced into the chamber body 112.

The lid assembly 140 includes at least two stacked components configured to form a plasma volume or cavity therebetween. In one or more embodiments, the lid assembly 140 includes a first electrode 143 (“upper electrode”) disposed vertically above a second electrode 145 (“lower electrode”) confining a plasma volume or cavity 150 therebetween. The first electrode 143 is connected to a power source 152, such as an RF power supply, and the second electrode 145 is connected to ground, forming a capacitance between the two electrodes 143, 145.

In one or more embodiments, the lid assembly 140 includes one or more gas inlets 154 (only one is shown) that are at least partially formed within an upper section 156 of the first electrode 143. The one or more process gases enter the lid assembly 140 via the one or more gas inlets 154. The one or more gas inlets 154 are in fluid communication with the plasma cavity 150 at a first end thereof and coupled to one or more upstream gas sources and/or other gas delivery components, such as gas mixers, at a second end thereof.

In one or more embodiments, the first electrode 143 has an expanding section 155 that bounds the plasma cavity 150. In one or more embodiments, the expanding section 155 is an annular member that has an inner surface or diameter 157 that gradually increases from an upper portion 155A thereof to a lower portion 155B thereof. As such, the distance between the first electrode 143 and the second electrode 145 is variable across the expanding section 155. The varying distance helps control the formation and stability of the plasma generated within the plasma cavity 150.

In one or more embodiments, the expanding section 155 resembles an inverted truncated cone or “funnel.” In one or more embodiments, the inner surface 157 of the expanding section 155 gradually slopes from the upper portion 155A to the lower portion 1558 of the expanding section 155. The slope or angle of the inner diameter 157 can vary depending on process requirements and/or process limitations. The length or height of the expanding section 155 can also vary depending on specific process requirements and/or limitations.

As mentioned above, the expanding section 155 of the first electrode 143 varies the vertical distance between the first electrode 143 and the second electrode 145 because of the gradually increasing inner surface 157 of the first electrode 143. The variable distance is directly influences to the power level within the plasma cavity 150. Not wishing to be bound by theory, the variation in distance between the two electrodes 143, 145 allows the plasma to find the necessary power level to sustain itself within some portion of the plasma cavity 150 if not throughout the entire plasma cavity 150. The plasma within the plasma cavity 150 is therefore less dependent on pressure, allowing the plasma to be generated and sustained within a wider operating window. As such, a more repeatable and reliable plasma can be formed within the lid assembly 140. As the plasma generated in the plasma cavity 150 is defined in the lid assembly 140 prior to entering into a processing region above the support assembly 180 wherein the substrate is proceed, the lid assembly 140 is considered as a remote plasma source because the plasma generated remotely from the processing region.

The expanding section 155 is in fluid communication with the gas inlet 154 as described above. The first end of the one or more gas inlets 154 can open into the plasma cavity 150 at the upper most point of the inner diameter of the expanding section 155. Similarly, the first end of the one or more gas inlets 154 can open into the plasma cavity 150 at any height interval along the inner diameter 157 of the expanding section 155. Although not shown, two gas inlets 154 can be disposed at opposite sides of the expanding section 155 to create a swirling flow pattern or “vortex” flow into the expanding section 155 which helps mix the gases within the plasma cavity 150.

The lid assembly 140 can further include an isolator ring 160 that electrically isolates the first electrode 143 from the second electrode 145. The isolator ring 160 can be made from aluminum oxide or any other insulative, process compatible material. The isolator ring 160 surrounds or substantially surrounds at least the expanding section 155.

The lid assembly 140 can further include a distribution plate 170 and blocker plate 175 adjacent the second electrode 145. The second electrode 145, distribution plate 170 and blocker plate 175 can be stacked and disposed on a lid rim 178 which is connected to the chamber body 112. A hinge assembly (not shown) can be used to couple the lid rim 178 to the chamber body 112. The lid rim 178 can include an embedded channel or passage 179 for circulating a heat transfer medium. The heat transfer medium can be used for heating, cooling, or both, depending on the process requirements.

In one or more embodiments, the second electrode or top plate 145 can include a plurality of gas passages or apertures 165 formed beneath the plasma cavity 150 to allow gas from the plasma cavity 150 to flow therethrough. The distribution plate 170 is substantially disc-shaped and also includes a plurality of apertures 172 or passageways to distribute the flow of gases therethrough. The apertures 172 can be sized and positioned about the distribution plate 170 to provide a controlled and even flow distribution to the processing region of the chamber body 112 where the substrate to be processed is located. Furthermore, the apertures 172 prevent the gas(es) from impinging directly on the substrate surface by slowing and re-directing the velocity profile of the flowing gases, as well as evenly distributing the flow of gas to provide an even distribution of gas across the surface of the substrate.

In one or more embodiments, the distribution plate 170 includes one or more embedded channels or passages 174 for housing a heater or heating fluid to provide temperature control of the lid assembly 140. A resistive heating element (not shown) can be inserted within the passage 174 to heat the distribution plate 170. A thermocouple can be connected to the distribution plate 170 to regulate the temperature thereof. The thermocouple can be used in a feedback loop to control electric current applied to the heating element, as described above.

Alternatively, a heat transfer medium can be passed through the passage 174. The one or more passages 174 can contain a cooling medium, if needed, to better control temperature of the distribution plate 170 depending on the process requirements within the chamber body 112. Any heat suitable transfer medium may be used, such as nitrogen, water, ethylene glycol, or mixtures thereof, for example.

In one or more embodiments, the lid assembly 140 can be heated using one or more heat lamps (not shown). Typically, the heat lamps are arranged about an upper surface of the distribution plate 170 to heat the components of the lid assembly 140 including the distribution plate 170 by radiation.

The blocker plate 175 may optionally be disposed between the second electrode 145 and the distribution plate 170. The blocker plate 175 is removably mounted to a lower surface of the second electrode 145. The blocker plate 175 may be in good thermal and electrical contact with the second electrode 145. In one or more embodiments, the blocker plate 175 can be coupled to the second electrode 145 using a bolt or similar fastener. The blocker plate 175 can also be threaded or screwed onto an outer diameter of the second electrode 145.

The blocker plate 175 includes a plurality of apertures 176 to provide a plurality of gas passages from the second electrode 145 to the distribution plate 170. The apertures 176 can be sized and positioned about the blocker plate 175 to provide a controlled and even flow distribution of gases to the distribution plate 170.

The support assembly 180 can include a support member 185 to support a substrate (not shown in FIG. 1) for processing within the chamber body 112. The support member 185 can be coupled to a lift mechanism 186 through a shaft 187 which extends through a centrally-located opening 114 formed in a bottom surface of the chamber body 112. The lift mechanism 186 can be flexibly sealed to the chamber body 112 by a bellows 188 that prevents vacuum leakage from around the shaft 187. The lift mechanism 186 allows the support member 185 to be moved vertically within the chamber body 112 between a process position and a lower transfer position. The transfer position is slightly below the opening of the slit valve 114 formed in a sidewall of the chamber body 112 so that the substrate may be robotically removed from the substrate support member 185.

In one or more embodiments, the support member 185 has a flat, circular surface or a substantially flat, circular surface for supporting a substrate to be processed thereon. The support member 185 may be constructed of aluminum. The support member 185 can include a removable top plate 190 made of some other material, such as silicon or ceramic material, for example, to reduce backside contamination of the substrate.

In one or more embodiments, the substrate (not shown) may be secured to the support member 185 using a vacuum chuck. In one or more embodiments, the substrate (not shown) may be secured to the support member 185 using an electrostatic chuck. An electrostatic chuck typically includes at least a dielectric material that surrounds an electrode 181, which may be located on the support member 185 or formed as an integral part of the support member 185. The dielectric portion of the chuck electrically insulates the chuck electrode 181 from the substrate and from the remainder of the support assembly 180.

In one embodiment, the electrode 181 is coupled to a plurality of RF power bias sources 184, 186. The RF bias power sources 184, 186 provide RF power to the electrode 181 which excites and sustains a plasma discharge formed from the gases disposed in the processing region of the chamber body.

In the embodiment depicted in FIG. 1, the dual RF bias power sources 184, 186 are coupled to the electrode 181 disposed in the support member 185 through a matching circuit 189. The signal generated by the RF bias power 184, 186 is delivered through matching circuit 189 to the support member 185 through a single feed to ionize the gas mixture provided in the plasma processing chamber 100, thereby providing ion energy necessary for performing a deposition, etch, or other plasma enhanced process. The RF bias power sources 184, 186 are generally capable of producing an RF signal having a frequency of from about 50 kHz to about 200 MHz and a power between about 0 Watts and about 5000 Watts. Additional bias power sources may be coupled to the electrode 181 to control the characteristics of the plasma as needed.

The support member 185 can include bores 192 formed therethrough to accommodate lift pins 193, one of which is shown in FIG. 1. Each lift pin 193 is constructed of ceramic or ceramic-containing materials, and are used for substrate-handling and transport. The lift pin 193 is moveable within its respective bore 192 when engaging an annular lift ring 195 disposed within the chamber body 112. The lift ring 195 is movable such that the upper surface of the lift-pin 193 can be extended above the substrate support surface of the support member 185 when the lift ring 195 is in an upper position. Conversely, the upper surface of the lift-pins 193 is located below the substrate support surface of the support member 185 when the lift ring 195 is in a lower position. Thus, each lift-pin 193 is moved in its respective bore 192 in the support member 185 when the lift ring 195 moves from either the lower position to the upper position.

The support assembly 180 can further include an edge ring 196 disposed about the support member 185. In one or more embodiments, the edge ring 196 is an annular member that is adapted to cover an outer perimeter of the support member 185 and protect the support member 185 from deposition. The edge ring 196 can be positioned on or adjacent the support member 185 to form an annular purge gas channel between the outer diameter of support member 185 and the inner diameter of the edge ring 196. The annular purge gas channel can be in fluid communication with a purge gas conduit 197 formed through the support member 185 and the shaft 187. The purge gas conduit 197 is in fluid communication with a purge gas supply (not shown) to provide a purge gas to the purge gas channel. Any suitable purge gas such as nitrogen, argon, or helium, may be used alone or in combination. In operation, the purge gas flows through the conduit 197, into the purge gas channel, and about an edge of the substrate disposed on the support member 185. Accordingly, the purge gas working in cooperation with the edge ring 196 prevents deposition at the edge and/or backside of the substrate.

The temperature of the support assembly 180 can be controlled by a fluid circulated through a fluid channel 198 embedded in the body of the support member 185. In one or more embodiments, the fluid channel 198 is in fluid communication with a heat transfer conduit 199 disposed through the shaft 187 of the support assembly 180. The fluid channel 198 is positioned about the support member 185 to provide a uniform heat transfer to the substrate receiving surface of the support member 185. The fluid channel 198 and heat transfer conduit 199 can flow heat transfer fluids to either heat or cool the support member 185 and substrate disposed thereon. Any suitable heat transfer fluid may be used, such as water, nitrogen, ethylene glycol, or mixtures thereof. The support assembly 185 can further include an embedded thermocouple (not shown) for monitoring the temperature of the support surface of the support member 185, which is indicative of the temperature of the substrate disposed thereon. For example, a signal from the thermocouple may be used in a feedback loop to control the temperature or flow rate of the fluid circulated through the fluid channel 198.

The support member 185 can be moved vertically within the chamber body 112 so that a distance between support member 185 and the lid assembly 140 can be controlled. A sensor (not shown) can provide information concerning the position of support member 185 within chamber 100.

In operation, the support member 185 can be elevated to a close proximity of the lid assembly 140 to control the temperature of the substrate being processed. As such, the substrate can be heated via radiation emitted from the distribution plate 170. Alternatively, the substrate can be lifted off the support member 185 to close proximity of the heated lid assembly 140 using the lift pins 193 activated by the lift ring 195.

A system controller (not shown) can be used to regulate the operations of the processing chamber 100. The system controller can operate under the control of a computer program stored on a memory of a computer. The computer program may include instructions that enable the process described below to be performed in the processing chamber 100. For example, the computer program can dictate the process sequencing and timing, mixture of gases, chamber pressures, RF power levels, susceptor positioning, slit valve opening and closing, substrate cooling and other parameters of a particular process.

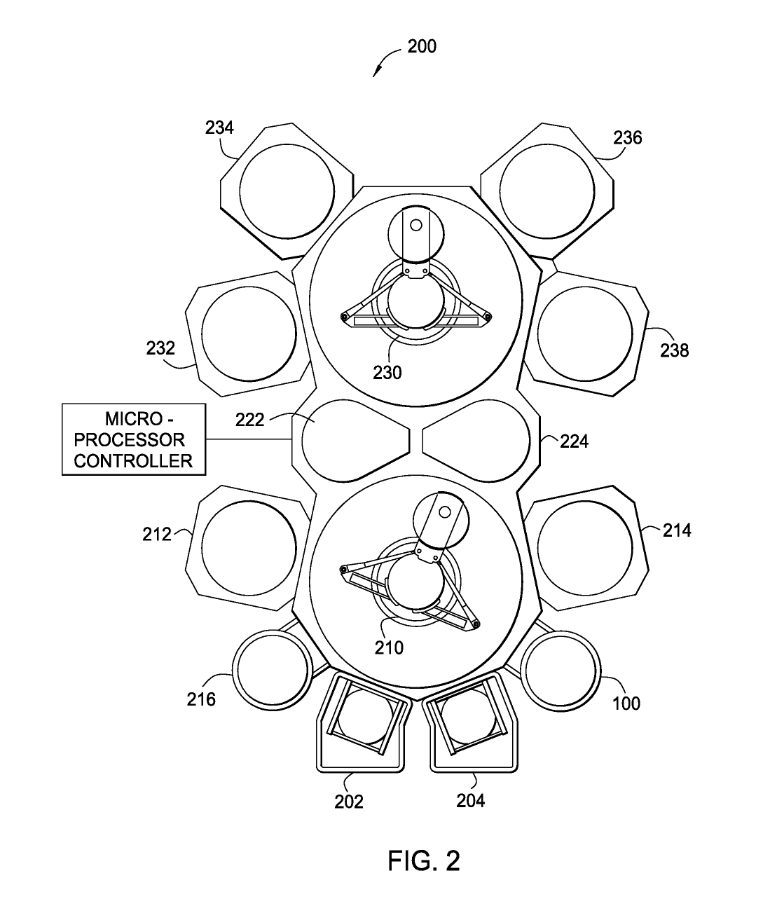

FIG. 2 is a schematic top-view diagram of an illustrative multi-chamber processing system 200 that can be adapted to perform processes as disclosed herein having the processing chamber 100 coupled thereto. The system 200 can include one or more load lock chambers 202, 204 for transferring substrates into and out of the system 200. Typically, since the system 200 is under vacuum, the load lock chambers 202, 204 can “pump down” the substrates being introduced into the system 200. A first robot 210 can transfer the substrates between the load lock chambers 202, 204, and a first set of one or more substrate processing chambers 212, 214, 216, 100 (four are shown). Each processing chamber 212, 214, 216, 100 is configured to perform at least one of substrate processing operation, such as an etching process, cyclical layer deposition (CLD), atomic layer deposition (ALD), chemical vapor deposition (CVD), physical vapor deposition (PVD), degas, orientation and other substrate processes. The position of the processing chamber 100 utilized to perform the etching process relative to the other chambers 212, 214, 216 is for illustration, and the position of the processing chamber 100 may be optionally be switched with any one of the processing chambers 212, 214, 216 if desired.

The first robot 210 can also transfer substrates to/from one or more transfer chambers 222, 224. The transfer chambers 222, 224 can be used to maintain ultra-high vacuum conditions while allowing substrates to be transferred within the system 200. A second robot 230 can transfer the substrates between the transfer chambers 222, 224 and a second set of one or more processing chambers 232, 234, 236, 238. Similar to processing chambers 212, 214, 216, 100, the processing chambers 232, 234, 236, 238 can be outfitted to perform a variety of substrate processing operations including the dry etch processes described herein any other suitable process including deposition, pre-clean, degas, and orientation, for example. Any of the substrate processing chambers 212, 214, 216, 100, 232, 234, 236, 238 can be removed from the system 200 if not necessary for a particular process to be performed by the system 200.

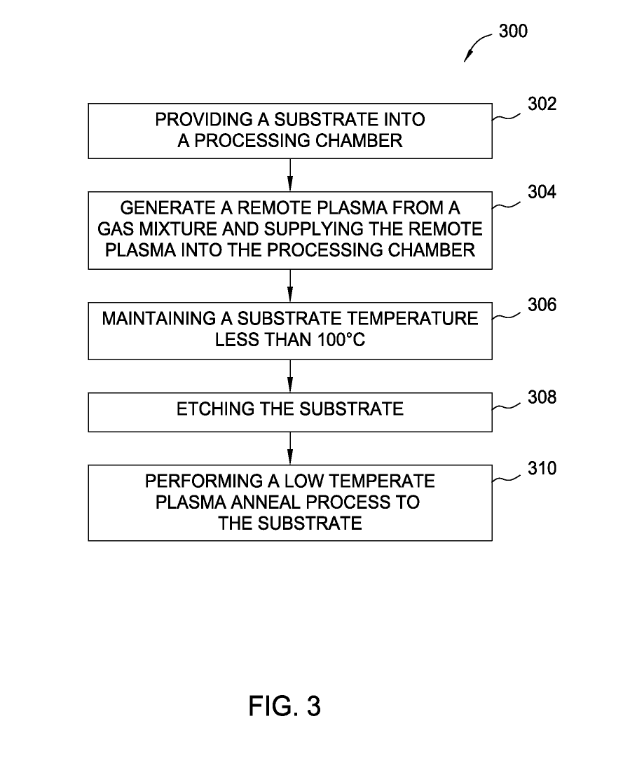

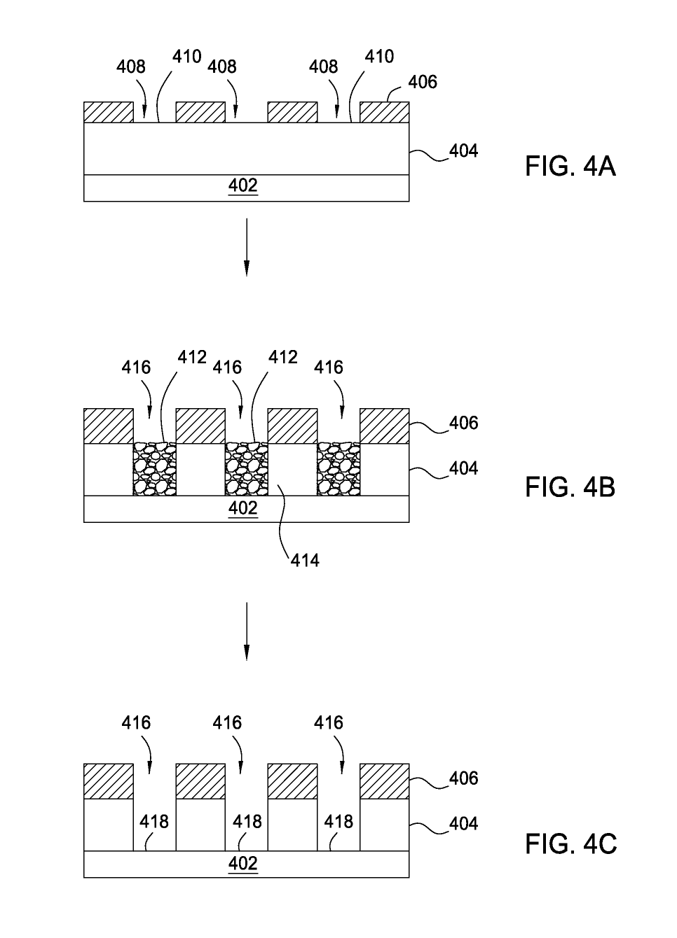

FIG. 3 illustrates a process sequence 300 used to perform an etching process to etch a material layer disposed on a substrate with high etching selectivity and good profile control. The sequence described in FIG. 3 corresponds to the fabrication stages depicted in FIGS. 4A-4C, which illustrates schematic cross-sectional views of a substrate 402 having a material layer 404 formed thereon during different stages of etching the material layer 404 illustrated by the processing sequence 300.

The process sequence 300 starts at block 302 by transferring a substrate, such as the substrate 402 depicted in FIG. 4A, into the processing chamber, such as the processing chamber 100 depicted in FIG. 1, or other suitable processing chamber. The substrate 402 may have a substantially planar surface, an uneven surface, or a substantially planar surface having a structure formed thereon. The substrate 402 shown in FIG. 4A includes a material layer 404 formed on the substrate 402. In one embodiment, the substrate 402 may be a material such as crystalline silicon (e.g., Si<100> or Si<111>), silicon oxide, strained silicon, silicon germanium, doped or undoped polysilicon, doped or undoped silicon wafers and patterned or non-patterned wafers silicon on insulator (SOI), carbon doped silicon oxides, silicon nitride, doped silicon, germanium, gallium arsenide, glass, sapphire. The substrate 402 may have various dimensions, such as 200 mm, 300 mm or 450 mm diameter wafers, as well as, rectangular or square panels. Unless otherwise noted, embodiments and examples described herein are conducted on substrates with a 300 mm diameter or a 450 mm diameter.

In one embodiment, the material layer 404 may be utilized to form a gate structure, shallow trench isolation (STI) structure, a contact structure or an interconnection structure in the front end or back end processes. In one embodiment, the method 300 may be performed on the material layer 404 to form a shallow trench isolation (STI) structure therein. The material layer 404 may be a dielectric layer selected from a group consisting of an oxide layer, a nitride layer, titanium nitride layer, a composite of oxide and nitride layer, at least one or more oxide layers sandwiching a nitride layer, and combinations thereof, among others. Other suitable materials for the material layer 404 also include undoped silicon glass (USG), such as silicon oxide or TEOS, boron-silicate glass (BSG), phosphorus-silicate glass (PSG), boron-phosphorus-silicate glass (BPSG) and combinations thereof. In an exemplary embodiment depicted herein, the material layer 404 is an undoped silicon glass (USG) layer. In one embodiment, the material layer 404 has a thickness between about 100 Å to about 15000 Å, such as between about 200 Å to about 5000 Å, for example about 2000 Å.

A patterned mask layer 406 is disposed on the material layer 404. The patterned mask layer 406 has an open feature 408 that exposes portions 410 of the material layer 404 for etching. In one embodiment, the mask layer 406 may be a hardmask layer, a photoresist mask or a combination thereof. The open feature 408 in the mask layer 406 is used as an etch mask to form open features 416 in the material layer 404 with desired aspect ratios and profile. The open features 416 described herein may include trenches, vias, openings and the like. In one embodiment wherein the mask layer 406 is a hardmask layer, the mask layer 406 may be a material selected from a group consisting of silicon, silicon oxide, silicon nitride, silicon oxynitride, silicon carbide, amorphous carbon, and combinations thereof. In some embodiments, the mask layer 406 may be a patterned photoresist layer, such as a lithographically patterned mask. The photoresist layer may is a positive tone photoresist, a negative tone photoresist, a UV lithography photoresist, an i-line photoresist, an e-beam resist (for example, a chemically amplified resist (CAR)) or other suitable photoresist.

At block 304, a remote plasma etching process is performed on the substrate 402 to etch the material layer 404 on the substrate 402, as shown in FIG. 4B. A remote plasma etching process is performed to slowly remove the material layer 404 exposed by the patterned mask layer 406 from the substrate 402. The remote plasma etching process is performed by supplying an etching gas mixture into the plasma cavity 150 into the processing chamber 100 to form a remote plasma source in the plasma cavity 150 from the processing gas mixture prior to flowing the processing gas for etching the material layer 404.

In one embodiment, the etching gas mixture used to remove the material layer 404 is a mixture of ammonia (NH₃) and nitrogen trifluoride (NF₃) gases. The amount of each gas introduced into the processing chamber may be varied and adjusted to accommodate, for example, the thickness of the material layer 404 to be removed, the geometry of the substrate being processed, the volume capacity of the plasma cavity, the volume capacity of the chamber body, as well as the capabilities of the vacuum system coupled to the chamber body.

As the plasma is generated remotely in the plasma cavity 150, the etchants dissociated from the etching gas mixture from the remote source plasma is relatively mild and gentle, so as to slowly, gently and gradually chemically react the material layer 404 until the underlying substrate 402 is exposed. It is believed that in the remote plasma source, ammonia (NH₃) gas and the nitrogen trifluoride (NF₃) gas are dissociated in the remote plasma cavity 150, forming ammonium fluoride (NH₄F) and/or ammonium fluoride with HF (NH₄F.HF). Once the etchants of ammonium fluoride (NH₄F) and ammonium fluoride with HF (NH₄F.HF) are introduced into the processing region of the processing chamber, reaching upon the substrate surface, the etchants of ammonium fluoride (NH₄F) and ammonium fluoride with HF (NH₄F.HF) may react with the dielectric materials, such as silicon oxide, forming (NH₄)₂SiF₆, mostly in a solid state. The etchants of ammonium fluoride (NH₄F) and ammonium fluoride with HF (NH₄F.HF) chemically react the material layer 404, forming (NH₄)₂SiF₆ in solid state, which will be later removed from the substrate surface by using a low temperature plasma anneal process, which will be discussed in further detail at block 310.

In one or more embodiments, the gases added to provide the etching gas mixture having at least a 1:1 molar ratio of ammonia (NH₃) to nitrogen trifluoride (NF₃). In one or more embodiments, the molar ratio of the etching gas mixture is at least about 3:1 (ammonia to nitrogen trifluoride). The gases are introduced in the chamber 100 at a molar ratio of from about 5:1 (ammonia to nitrogen trifluoride) to about 30:1. In yet another embodiment, the molar ratio of the etching gas mixture is from about 5:1 (ammonia to nitrogen trifluoride) to about 10:1. The molar ratio of the etching gas mixture can also fall between about 10:1 (ammonia to nitrogen trifluoride) and about 20:1.

In one embodiment, other types of gas, such as inert gas or carrier gas, may also be supplied in the etching gas mixture to assist carrying the etching gas mixture into the processing region of the vacuum processing chamber 100. Suitable examples of the inert gas or carrier gas include at least one of Ar, He, N₂, O₂, N₂O, NO₂, NO, and the like. In one embodiment, the inert or carrier gas may be supplied into the vacuum processing chamber 100 is Ar or He at a volumetric flow rate between about 200 sccm and about 1500 sccm.

At block 306, while supplying the etching gas mixture to perform the remote plasma source etching process, a substrate temperature may be maintained at a low range, such as less than about 100 degrees Celsius, such as between about 40 degrees Celsius and about 100 degrees Celsius. It is believed that maintaining the substrate temperature at a low range, such as less than 100 degrees Celsius, may assist increasing the etching rate of the etching process. It is believed that overly high temperature will restrain chemical reaction between ammonia (NH₃) and nitrogen trifluoride (NF₃) to form the desired etchants, ammonium fluoride (NH₄F) and/or ammonium fluoride with HF (NH₄F.HF), for etching. As nitrogen trifluoride (NF₃) is relatively thermodynamically stable at elevated temperatures, a low temperature utilized during the etching process may favors surface adsorption of plasma of plasma species onto the material layer 404 being etched. Therefore, controlling the substrate temperature at a range less than about 100 degrees Celsius may desirably enhance the etching rate during the etching process, thereby increasing the overall etching process throughput.

During the etching process, several process parameters may be regulated to control the etching process. In one exemplary embodiment, a process pressure in the processing chamber 100 is regulated between about 10 mTorr to about 5000 mTorr, such as between about 800 mTorr and about 5 Torr. A RF source power at a frequency of about 80 KHz may be applied to maintain a plasma in the chemical etching gas mixture. For example, a RF source power of about between 20 Watts to about 70 Watts may be applied to the etching gas mixture. The RF source power as referred here may be the RF power supplied from the power source 152 to the electrodes 143, 145. In one embodiment, the RF source power may have a frequency of about 80 KHz. Additionally, a RF bias power may be supplied to the electrode 181 to generate a bias power. For example, a RF bias power at a frequency of about 13 or 60 MHz of between about 10 Watts to about 1000 Watts may be applied to the etching gas mixture. The etching gas mixture may be flowed into the chamber at a rate between about 400 sccm to about 2000 sccm.

At block 308, after the etching gas mixture is supplied into the processing chamber with a low temperature substrate control, such as less than about 100 degrees Celsius, the material layer 404 may be then etched, forming solid etching byproduct 412, ammonium fluorosilicate (NH₄)₂SiF₆, on the substrate surface, as shown in FIG. 4B. The etching byproduct 412, (NH₄)₂SiF₆, remaining on the substrate has a relatively low melting point, such as about 100 degrees Celsius, which may be removed from the substrate by a sublimation process, which will be further discussed below at block 310. The etching process may be continuously performed until the material layer 404 disposed on the substrate 402 has all been reacted and converted to the ending byproduct 412, such as ammonium fluorosilicate (NH₄)₂SiF₆.

In one embodiment, the etching process may be performed for between about 60 seconds and about 2000 seconds.

At block 310, after the etching process is completed and the material layer 404 has substantially reacted and converted to the etching byproduct 412, such as ammonium fluorosilicate (NH₄)₂SiF₆, a low temperature plasma anneal process is performed to sublimate the ending byproduct 412 in volatile state to be pumped out of the processing chamber. The low temperature plasma anneal process may be performed in the same chamber where the low temperature etching process at block 308 is performed, such as the processing chamber 100 as described above. Alternatively, the low temperature plasma anneal process may be performed at a separate processing chamber of the system 200 as needed.

During the low temperature plasma anneal process, the substrate temperature is maintained low, such as a low temperature range less than about 100 degrees Celsius. Conventional high temperature anneal processes may not only adversely increase the overall process time (e.g., an additional process step or waiting time to elevate substrate support member temperature from low temperature etching process to high temperature for annealing), but also affect the chemical reaction and the etching byproduct removal rate during the anneal process. Additionally, conventional high temperature annealing processes often causes damage to the substrate and increases condensation of the other etching byproducts adhering on the substrate surface. Therefore, by utilizing a low temperature plasma anneal process, not only can throughout be improved (e.g., by not requiring a temperature change from the etching process previously performed at block 308), but also the etching byproduct cleaning efficiency may be improved, by the nature of the low melting (sublimation) point to the etching byproduct 412, such as ammonium fluorosilicate (NH₄)₂SiF₆.

In one embodiment, the low temperature plasma anneal process may utilize a low RF bias power plasma treatment process to gently and mildly treat the substrate without damaging to the substrate surface. In one embodiment, the low temperature plasma process may use a low RF bias power, such as less than about 300 Watts, along with controlling the substrate temperature less than about 100 degrees Celsius, to sublimate the etching byproducts 412 from the substrate surface.

The low temperature plasma anneal process is performed by supplying a plasma anneal gas mixture into the chamber 100. A plasma is then formed from the plasma anneal gas mixture to plasma anneal the substrate 402, forming volatile gas byproducts which readily pumps out of the processing chamber 100.

In one embodiment, the plasma anneal gas mixture includes at least one of a hydrogen containing gas, a nitrogen containing gas, or an inert gas. It is believed that the hydrogen containing gas, the nitrogen containing gas, or inert gas supplied in the plasma anneal gas mixture may assist increasing the lifetime of the ions in the plasma formed from the plasma anneal gas mixture, thereby efficiently removing the etching byproducts 412 from the substrate 420. Increased lifetime of the ions may assist reacting with and activating the etching byproduct 412 on the substrate 402 more thoroughly, thereby enhancing the removal of the etching byproduct 412 from the substrate 402.

In one embodiment, the hydrogen containing gas supplied into the processing chamber 100 includes at least one of H₂, H₂O, and the like. The nitrogen containing gas supplied into the processing chamber 100 includes at N₂, N₂O, NO₂, NH₃ and the like. The inert gas supplied into the processing chamber 100 includes at least one of Ar, He, Kr, and the like. In an exemplary embodiment, the hydrogen containing gas supplied in the processing chamber 100 to perform the treatment process is H₂ gas, and the nitrogen containing gas supplied in the processing chamber 100 to perform the treatment process is N₂ gas and the inert gas is He or Ar.

During the plasma anneal process, several process parameters may be regulated to control the pretreatment process. In one exemplary embodiment, a process pressure in the processing chamber 100 is regulated between about 10 mTorr to about 5000 mTorr, such as between about 10 mTorr and about 200 mTorr. A RF bias power at a frequency of about 13 MHz may be applied to maintain a plasma in the treatment gas mixture. For example, a RF bias power of about 20 Watts to about 300 Watts may be applied to maintain a plasma inside the processing chamber 100. The plasma anneal gas mixture may be flowed into the chamber at a rate between about 100 sccm to about 1000 sccm. A substrate temperature is maintained less than 100 degrees Celsius, for example between about room temperature to about 100 degrees Celsius, such as between about 40 degrees Celsius and about 100 degrees Celsius. In some embodiment, no power is applied to the electrodes 143, 145.

Thus, a method and an apparatus for a low temperature etching process along with a low temperature plasma anneal process with high etching selectivity and good profile control are provided. The method may gradually etch a material layer with good interface control while providing an acceptable range of overall etching throughput.

While the foregoing is directed to embodiments of the present invention, other and further embodiments of the invention can be devised without departing from the basic scope thereof, and the scope thereof is determined by the claims that follow.

1. A method for etching a material layer disposed on a substrate, comprising:
supplying an etching gas mixture to a substrate having a material layer disposed thereon into an etching processing chamber;
remotely generating a plasma in the etching gas mixture to etch the material layer disposed on the substrate; and
plasma annealing the material layer by generating a RF bias power in the processing chamber at a substrate temperature less than 100 degrees Celsius.

2. The method of claim 1, wherein the step of plasma annealing the material layer further comprises:
supplying a plasma annealing gas mixture into the processing chamber.

3. The method of claim 2, wherein supplying the plasma annealing gas mixture further comprises:
generating a plasma from the plasma annealing gas mixture to plasma anneal the substrate.

4. The method of claim 2, wherein the plasma annealing gas mixture includes at least one of hydrogen containing gas, a nitrogen containing gas or an inert gas.

5. The method of claim 3, wherein generating the plasma in the plasma annealing gas mixture further comprises:
applying less than 300 Watts of the RF bias power to the plasma annealing gas mixture.

6. The method of claim 1, wherein supplying the etching gas mixture further comprises:
supplying an ammonium gas and a nitrogen trifluoride in the etching gas mixture in a molar ratio of about 5:1 to about 30:1.

7. The method of claim 1, wherein supplying the etching gas mixture further comprises:
maintaining a substrate temperature less than about 100 degrees Celsius.

8. The method of claim 1, wherein plasma annealing the material layer further comprises:
sublimating an etching byproduct from the substrate.

9. The method of claim 1, wherein the material layer is a silicon oxide layer.

10. The method of claim 1, wherein remotely generating the plasma in the etching gas mixture further comprises:
applying a RF source power to remotely generate the plasma from the etching gas mixture.

11. The method of claim 10, wherein the RF source power has a frequency of about 80 KHz.

12. A method for etching a material layer disposed on a substrate, comprising:
performing an etching process in a processing chamber to etch a material layer exposed by a patterned mask layer disposed on a substrate, wherein a substrate temperature during the etching process is controlled less than about 100 degrees Celsius; and
performing a plasma anneal process on the etched material layer by generating a RF bias power in the processing chamber, wherein the substrate temperature during the plasma anneal process is controlled less than about 100 degrees Celsius.

13. The method of claim 12, wherein performing an etching process further comprises:
remotely generating a plasma from an etching gas mixture to etch the material layer.

14. The method of claim 13, wherein the etching gas mixture includes an ammonium gas and a nitrogen trifluoride provided at a molar ratio of about 5:1 to about 30:1.

15. The method of claim 12, wherein performing the plasma anneal process further comprises:
supplying a plasma anneal gas mixture into the processing chamber, wherein the plasma anneal gas mixture includes at least one of hydrogen containing gas, a nitrogen containing gas or an inert gas.

16. The method of claim 15, further comprising:
applying the RF bias power less than about 300 Watts to generate a plasma from the plasma anneal gas mixture.

17. The method of claim 12, wherein performing the plasma anneal process on the etched material layer further comprises:
sublimating etching byproducts from the substrate.

18. The method of claim 12, wherein the material layer is a silicon oxide layer configured to form a shallow trench isolation structure.

19. A method for etching a material layer on a substrate comprising:
remotely generating a plasma from an etching gas mixture to a substrate having a material layer disposed thereon into a processing chamber, the etching gas mixture including an ammonium gas and a nitrogen trifluoride;
controlling a substrate temperature less than about 100 degrees Celsius;
etching the material layer from the substrate utilizing the etching gas mixture;
subsequently supplying a plasma anneal gas mixture to plasma anneal the etched material layer into the processing chamber;
applying less than about 300 Watts of a RF bias power to the plasma anneal gas mixture;
controlling the substrate temperature less than about 100 degrees Celsius; and
sublimating an etching byproduct from the substrate.

20. The method of claim 19, wherein the plasma anneal gas mixture includes at least one of hydrogen containing gas, a nitrogen containing gas or an inert gas.
